(19) United States
(12) Patent Application Publication
(10) Pub. No.: US 2024/0429293 A1
(43) Pub. Date: Dec. 26, 2024

(54) SEMICONDUCTOR APPARATUS

(71) Applicant: ROHM Co., LTD., Kyoto (JP)

(72) Inventors: Kazuki Yoshida, Kyoto (JP); Hajime Kataoka, Kyoto (JP)

(21) Appl. No.: 18/753,126

(22) Filed: Jun. 25, 2024

(30) Foreign Application Priority Data
Jun. 26, 2023 (JP) 2023-104228

(51) Int. Cl. H01L 29/417; H01L 29/40; H01L 29/423; H01L 29/78

(52) U.S. Cl. CPC H01L 29/41741; H01L 29/407; H01L 29/4236; H01L 29/7813

(57) ABSTRACT

Provided is a semiconductor apparatus including a body region formed on a drift region, a body contact region formed on the body region, a gate trench formed to penetrate both the body region and the body contact region and reach the drift region, the gate trench including a side wall and a bottom wall, a source region formed along part of the side wall, the source region being in contact with both the body region and the body contact region, and source wiring arranged across both the gate trench and the body region as viewed in a depth direction of the gate trench. The source region includes a source contact region that is in contact with the source wiring. The source wiring is in contact with both a side surface of the source contact region and a front surface of the body contact region.

### CROSS REFERENCE TO RELATED APPLICATIONS

This application claims priority benefit of Japanese Patent Application No. JP 2023-104228 filed in the Japan Patent Office on Jun. 26, 2023. Each of the above-referenced applications is hereby incorporated herein by reference in its entirety.

### BACKGROUND

The present disclosure relates to a semiconductor apparatus.

A metal insulator semiconductor field effect transistor (MISFET) with a split-gate structure is disclosed in Japanese Patent Laid-Open No. 2022-146898.

The MISFET of Japanese Patent Laid-Open No. 2022-146898 includes a contact trench that penetrates a source region between a plurality of trenches in a semiconductor layer and reaches a body region, a contact region formed on a bottom wall of the contact trench, and a source contact implanted into the contact trench. Source wiring of the MISFET is electrically connected to the source contact.

### BRIEF DESCRIPTION OF THE DRAWINGS

FIG. 1 is a schematic plan view of an exemplary semiconductor apparatus according to an embodiment;

FIG. 2 is a schematic cross-sectional view of the semiconductor apparatus cut along line F2-F2 of FIG. 1;

FIG. 3 is an enlarged schematic cross-sectional view of one gate trench of FIG. 2 and around the gate trench;

FIG. 4 is an enlarged schematic cross-sectional view of a mesa region of FIG. 2 and around the mesa region;

FIG. 5 is a schematic cross-sectional view illustrating an exemplary manufacturing process of the semiconductor apparatus according to the embodiment;

FIG. 6 is a schematic cross-sectional view illustrating a manufacturing process following the process illustrated in FIG. 5;

FIG. 7 is a schematic cross-sectional view illustrating a manufacturing process following the process illustrated in FIG. 6;

FIG. 8 is a schematic cross-sectional view illustrating a manufacturing process following the process illustrated in FIG. 7;

FIG. 9 is a schematic cross-sectional view illustrating a manufacturing process following the process illustrated in FIG. 8;

FIG. 10 is a schematic cross-sectional view illustrating a manufacturing process following the process illustrated in FIG. 9;

FIG. 11 is a schematic cross-sectional view illustrating a manufacturing process following the process illustrated in FIG. 10;

FIG. 12 is a schematic cross-sectional view illustrating a manufacturing process following the process illustrated in FIG. 11;

FIG. 13 is a schematic cross-sectional view illustrating a manufacturing process following the process illustrated in FIG. 12;

FIG. 14 is a schematic cross-sectional view illustrating a manufacturing process following the process illustrated in FIG. 13;

FIG. 15 is a schematic cross-sectional view illustrating a manufacturing process following the process illustrated in FIG. 14;

FIG. 16 is a schematic cross-sectional view illustrating a manufacturing process following the process illustrated in FIG. 15;

FIG. 17 is a schematic cross-sectional view illustrating a manufacturing process following the process illustrated in FIG. 16;

FIG. 18 is a schematic cross-sectional view illustrating a manufacturing process following the process illustrated in FIG. 17;

FIG. 19 is a schematic cross-sectional view illustrating a manufacturing process following the process illustrated in FIG. 18;

FIG. 20 is a schematic cross-sectional view illustrating a manufacturing process following the process illustrated in FIG. 19;

FIG. 21 is a schematic cross-sectional view of an exemplary semiconductor apparatus according to a change example; and

FIG. 22 is a schematic cross-sectional view of an exemplary semiconductor apparatus according to another change example.

### DETAILED DESCRIPTION

A semiconductor apparatus according to some embodiments of the present disclosure will be described with reference to the attached drawings. Note that, in order to simplify and clarify the description, constituent elements illustrated in the drawings may not be depicted in a constant reduced scale. To facilitate the understanding, hatch lines are not illustrated in the cross-sectional views in some cases. The attached drawings merely illustrate embodiments of the present disclosure and should not be construed as limiting the present disclosure.

The following detailed description includes apparatuses, systems, and methods for embodying exemplary embodiments of the present disclosure. The detailed description is fundamentally merely for the explanation and is not intended to limit the embodiments of the present disclosure or the application and use of the embodiments.

### [Planar Structure of Semiconductor Apparatus]

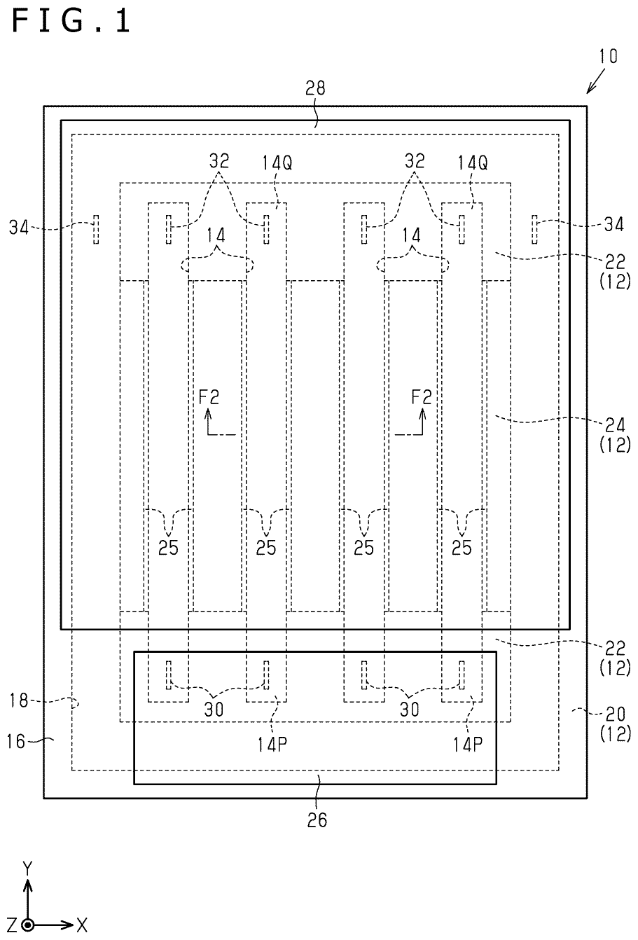

A planar structure of the semiconductor apparatus of an embodiment will be described with reference to FIG. 1.

FIG. 1 illustrates a schematic planar structure of an exemplary semiconductor apparatus 10 according to the embodiment. Note that the term “in plan view” used in the present disclosure represents viewing the semiconductor apparatus 10 in a Z direction of X, Y, and Z axes orthogonal to each other illustrated in FIG. 1. Unless explicitly stated otherwise, “in plan view” represents viewing the semiconductor apparatus 10 from above along the Z axis.

The semiconductor apparatus 10 is, for example, a MISFET with a split-gate structure. The semiconductor apparatus 10 includes a semiconductor layer 12, a gate trench 14 formed on the semiconductor layer 12, and an insulating layer 16 formed in the gate trench 14.

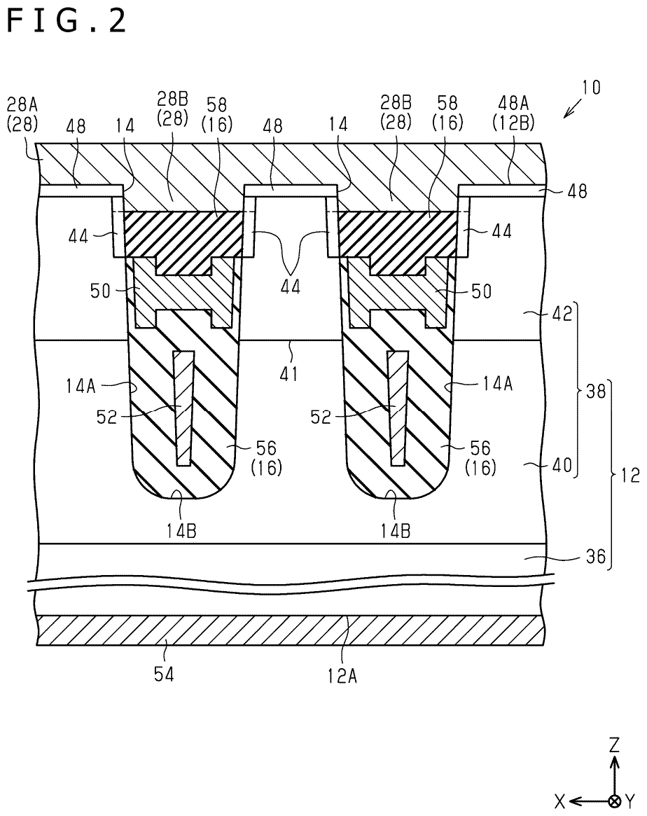

The semiconductor layer 12 can be formed by, for example, silicon (Si). The semiconductor layer 12 includes a first surface 12A and a second surface 12B on the opposite side of the first surface 12A (see FIG. 2 for the surfaces 12A and 12B). The semiconductor layer 12 has a thickness in a direction (Z direction) perpendicular to the first surface 12A. It can be stated that the Z direction is a “thickness direction of the semiconductor layer 12.”

The gate trench 14 includes an opening on the second surface 12B of the semiconductor layer 12 and has a depth in the Z direction. Therefore, it can be stated that the gate trench 14 is formed on the second surface 12B. The gate trench 14 extends in a Y direction in plan view and has a width in an X direction. In the present specification, the Z direction will also be referred to as a “depth direction of the gate trench 14,” and the X direction will also be referred to as a “width direction of the gate trench 14.”

The semiconductor apparatus 10 includes a plurality of (four in the example of FIG. 1) gate trenches 14. The plurality of gate trenches 14 can be aligned in stripes. In one example, the plurality of gate trenches 14 may be arrayed at equal intervals in the X direction in plan view. Gate electrodes 50 and field plate electrodes 52 described later with reference to FIG. 2 can be arranged in the gate trenches 14. Each gate trench 14 includes a first end portion 14P and a second end portion 140 that are end portions in the Y direction. The field plate electrode 52 here is one example of an “implanted electrode.”

The semiconductor apparatus 10 may further include a peripheral trench 18 formed on the semiconductor layer 12. The peripheral trench 18 can be separated from the gate trenches 14 and formed to surround the plurality of gate trenches 14 in plan view. In the example illustrated in FIG. 1, the peripheral trench 18 is formed in a rectangular frame shape in which the X direction is the transverse direction and the Y direction is the longitudinal direction. A peripheral electrode (not illustrated) formed along the shape of the peripheral trench 18 can be arranged in the peripheral trench 18.

As illustrated in FIG. 1, the second surface 12B of the semiconductor layer 12 can include an n− region 20 containing n-type impurities, a p− region 22 containing p-type impurities, a p+ region 24 containing p-type impurities, and an n+ region 25 containing n-type impurities. The n− region 20 may surround the peripheral trench 18. The p− region 22, the p+ region 24, and the n+ region 25 may be surrounded by the peripheral trench 18. That is, the n− region 20, the p− region 22, the p+ region 24, and the n+ region 25 are defined by the peripheral trench 18.

The p− region 22 and the p+ region 24 are lined up in the Y direction. A plurality of (two in the example of FIG. 1) p− regions 22 may be provided. The two p− regions 22 are, for example, dispersed and provided on both sides in the Y direction of the p+ region 24. In other words, the p+ region 24 can be positioned between the two p− regions 22 in the Y direction.

The n+ region 25 is arranged at a position overlapping the p+ region 24 in plan view. The n+ region 25 is arranged closer to the first surface 12A in the Z direction than the p+ region 24 is. A plurality of n+ regions 25 are formed. The plurality of n+ regions 25 are separated from each other and arrayed in the X direction. In the example illustrated in FIG. 1, the n+ regions 25 are extended along the Y direction on both sides in the X direction of the gate trenches 14.

Each gate trench 14 can be arranged adjacent to both the p− region 22 and the p+ region 24. The first end portion 14P of the gate trench 14 can be adjacent to one of the two p− regions 22, and the second end portion 140 of the gate trench 14 can be adjacent to the remaining one of the two p− regions 22. Meanwhile, the middle part of the gate trench 14 can be adjacent to the p+ region 24.

The insulating layer 16 covers the region other than the p+ region 24 in the second surface 12B of the semiconductor layer 12, and the insulating layer 16 is implanted into the gate trenches 14 and the peripheral trench 18. The insulating layer 16 is a layer that insulates the gate electrodes 50 and the field plate electrodes 52 from the semiconductor layer 12.

The semiconductor apparatus 10 can further include gate wiring 26 and source wiring 28 formed on the insulating layer 16. The gate wiring 26 and the source wiring 28 can each be arranged to cover part of the gate trenches 14 and part of the peripheral trench 18. The gate wiring 26 can be arranged to at least partially overlap one of the two p− regions 22. The source wiring 28 can be arranged to at least partially overlap the other one of the two p− regions 22. The source wiring 28 may be separated from the gate wiring 26 and may cover at least the entire p+ regions 24.

The gate wiring 26 and the source wiring 28 can be formed by a material containing at least one of titanium (Ti), nickel (Ni), gold (Au), silver (Ag), copper (Cu), aluminum (Al), Cu alloy, and Al alloy.

The semiconductor apparatus 10 can further include a plurality of gate contacts 30. Each gate contact 30 can connect the gate electrode 50 (see FIG. 2) arranged in each gate trench 14 to the gate wiring 26. The gate contact 30 can extend in the Z direction in such a manner as to penetrate the insulating layer 16 positioned between the gate electrode 50 and the gate wiring 26. The gate contact 30 can be arranged in a region where the gate trench 14 and the gate wiring 26 overlap in plan view. More specifically, the gate contact 30 can be arranged in a region where the first end portion 14P of the gate trench 14 and the gate wiring 26 overlap in plan view.

The semiconductor apparatus 10 can further include a plurality of source contacts 32. Each source contact 32 can connect the field plate electrode 52 arranged in each gate trench 14 to the source wiring 28. The source contact 32 can extend in the Z direction in such a manner as to penetrate the insulating layer 16 positioned between the field plate electrode 52 and the source wiring 28. The source contact 32 can be arranged in a region where the gate trench 14 and the source wiring 28 overlap in plan view. More specifically, the source contact 32 can be arranged in a region where the second end portion 140 of the gate trench 14 and the source wiring 28 overlap in plan view.

The semiconductor apparatus 10 may further include one or a plurality of contacts 34 that connect the peripheral electrodes (not illustrated) arranged in the peripheral trench 18 to the source wiring 28. The number and the arrangement position of the contacts 34 are not limited to the example illustrated in FIG. 1 and can be changed as desired.

The gate contacts 30, the source contacts 32, and the contacts 34 can be formed by a desired metal material. In one example, the contacts 30, 32, and 34 can be formed by a material containing at least one of tungsten (W), Ti, and titanium nitride (TiN).

### [Cross-Sectional Structure of Semiconductor Apparatus]

A cross-sectional structure of the semiconductor apparatus 10 will be described with reference to FIGS. 2 to 4.

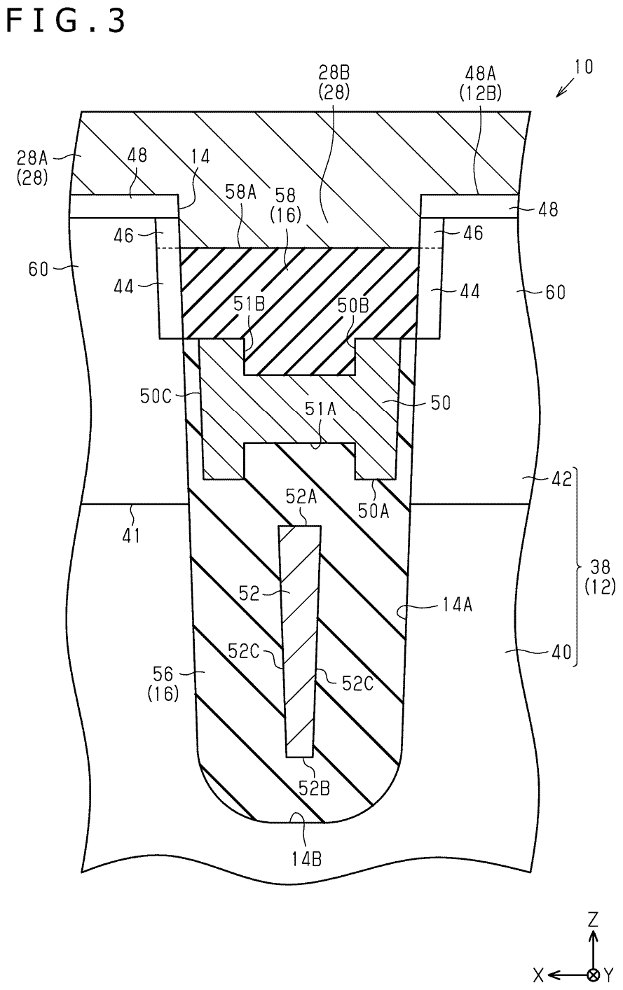

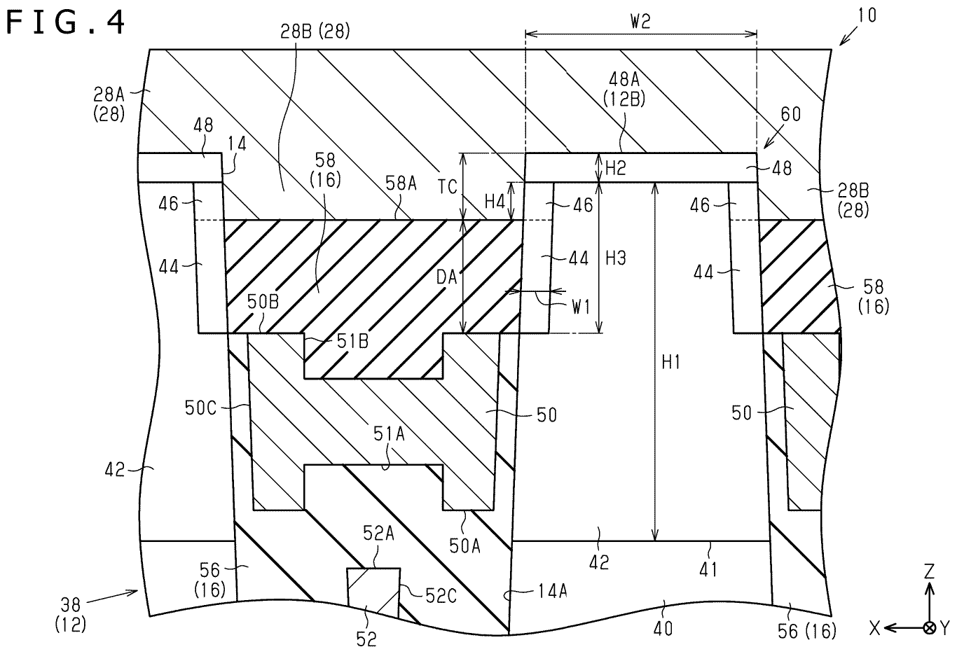

FIG. 2 illustrates a schematic cross-sectional structure of the semiconductor apparatus 10 of FIG. 1 cut along line F2-F2. FIG. 3 illustrates an enlarged schematic cross-sectional structure of one gate trench 14 of FIG. 2 and around the gate trench 14. FIG. 4 illustrates an enlarged schematic cross-sectional structure of the opening portion of the gate trench 14 of FIG. 3 and around the opening portion.

The semiconductor layer 12 can include a semiconductor substrate 36 including the first surface 12A of the semiconductor layer 12, and an epitaxial layer 38 that is formed on the semiconductor substrate 36 and that includes the second surface 12B of the semiconductor layer 12. The semiconductor substrate 36 may be formed by a material containing Si. In one example, the semiconductor substrate 36 may be a Si substrate. The semiconductor substrate 36 can correspond to a drain region of the MISFET. Therefore, the semiconductor substrate 36 will be referred to as a “drain region 36” in some cases. The epitaxial layer 38 may be a Si layer epitaxially grown on the Si substrate. The epitaxial layer 38 can include a drift region 40, a body region 42 formed on the drift region 40, and a source region 44 formed on part of the body region 42.

The drain region 36 (semiconductor substrate 36) may be an n+ region containing n-type impurities. The n-type impurity concentration of the drain region 36 can be, for example, equal to or greater than 1×10¹⁸ cm⁻³ but equal to or smaller than 1×10²⁰ cm⁻³. The thickness of the drain region 36 may be, for example, equal to or greater than 50 μm but equal to or smaller than 450 μm.

The drift region 40 may be an n− region containing n-type impurities with the concentration lower than that of the drain region 36. The n-type impurity concentration of the drift region 40 can be, for example, equal to or greater than 1×10¹⁵ cm⁻³ but equal to or smaller than 1×10¹⁸ cm⁻³. The thickness of the drift region 40 may be, for example, equal to or greater than 1 μm but equal to or smaller than 25 μm.

The body region 42 may be a p− region containing p-type impurities. The p-type impurity concentration of the body region 42 can be, for example, equal to or greater than 1×10¹⁶ cm⁻³ but equal to or smaller than 1×10¹⁸ cm⁻³. The thickness of the body region 42 can be, for example, equal to or greater than 0.5 μm but equal to or smaller than 1.5 μm.

The source region 44 may be an n+ region containing n-type impurities with the concentration higher than that of the drift region 40. The impurity concentration of the source region 44 may be higher than the impurity concentration of the body region 42. The n-type impurity concentration of the source region 44 can be, for example, equal to or greater than 1×10¹⁹ cm⁻³ but equal to or smaller than 1×10²¹ cm⁻³. The source region 44 corresponds to the n+ region 25 illustrated in FIG. 1. That is, the dimension in the Y direction of the source region 44 is smaller than the dimension in the Y direction of the gate trench 14.

A body contact region 48 can include the second surface 12B of the semiconductor layer 12. A front surface 48A (second surface 12B) of the body contact region 48 corresponds to the p+ region 24 illustrated in FIG. 1. That is, the dimension in the Y direction of the body contact region 48 is smaller than the dimension in the Y direction of the gate trench 14. The dimension in the Y direction of the body contact region 48 is equal to the dimension in the Y direction of the source region 44.

The body contact region 48 may be a p+ region containing p-type impurities. The body contact region 48 is formed in a surface layer region of the body region 42. More specifically, the body contact region 48 is formed between two gate trenches 14 adjacent to each other in the X direction in the body region 42. The p-type impurity concentration of the body contact region 48 is higher than that of the body region 42 and can be, for example, equal to or greater than 1×10¹⁹ cm⁻³ but equal to or smaller than 1×10²¹ cm⁻³.

Note that, in the present disclosure, the n type will also be referred to as a first conductivity type and the p type will also be referred to as a second conductivity type. The n-type impurities may be, for example, phosphorus (P) or arsenic (As). The p-type impurities may be, for example, boron (B) or aluminum (Al).

The gate trench 14 includes a side wall 14A and a bottom wall 14B, and the bottom wall 14B is adjacent to the drift region 40. That is, the gate trench 14 penetrates the body region 42 of the semiconductor layer 12 and reaches the drift region 40. The depth of the gate trench 14 may be, for example, equal to or greater than 1 μm but equal to or smaller than 10 μm. The depth of the gate trench 14 can be defined as a distance in the Z direction from the second surface 12B of the semiconductor layer 12 to the bottom wall 14B of the gate trench 14 (deepest part of the gate trench 14 when the bottom wall 14B is curved). The Z direction here corresponds to the “depth direction of the gate trench 14 (trench).”

The side wall 14A of the gate trench 14 may be, for example, tilted with respect to the Z direction such that the width of the gate trench 14 becomes smaller toward the bottom wall 14B. The side wall 14A may also be extended in the direction (Z direction) perpendicular to the second surface 12B of the semiconductor layer 12. In the example illustrated in FIG. 2, the bottom wall 14B of the gate trench 14 includes a flat portion formed at the center in the X direction and curved portions formed on both sides in the X direction of the flat portion. The curved portion is a part that connects the flat portion and the side wall 14A to each other. Note that the configuration of the bottom wall 14B can be changed as desired. For example, the entire bottom wall 14B may be a flat portion, or the entire bottom wall 14B may be a curved portion.

The semiconductor apparatus 10 can further include the gate electrode 50 arranged in the gate trench 14 and the field plate electrode 52 arranged in the gate trench 14 and separated downward from the gate electrode 50 in the Z direction.

As illustrated in FIG. 3, the field plate electrode 52 includes an opposing surface 52A opposing the gate electrode 50 through the insulating layer 16, a bottom surface 52B opposing the bottom wall 14B of the gate trench 14 through the insulating layer 16, and a side surface 52C that connects the opposing surface 52A and the bottom surface 52B to each other. The opposing surface 52A of the field plate electrode 52 is positioned closer to the bottom wall 14B of the gate trench 14 in the Z direction than the gate electrode 50 is.

The gate electrode 50 can include a bottom surface 50A at least partially opposing the opposing surface 52A of the field plate electrode 52, a front surface 50B on the opposite side of the bottom surface 50A, and a side surface 50C that connects the bottom surface 50A and the front surface 50B to each other. At least part of the bottom surface 50A of the gate electrode 50 may oppose the opposing surface 52A of the field plate electrode 52 in the Z direction. In one example, the front surface 50B of the gate electrode 50 is positioned closer to the bottom wall 14B of the gate trench 14 than the second surface 12B of the semiconductor layer 12 is.

The gate electrode 50 is arranged closer to the second surface 12B than an interface 41 of the body region 42 and the drift region 40 is. More specifically, the bottom surface 50A of the gate electrode 50 is arranged closer to the second surface 12B than the interface 41 is. Note that the bottom surface 50A may be at the same position as the interface 41 in the Z direction or may be closer to the bottom wall 14B than the interface 41 is.

The gate electrode 50 includes a bottom surface side recessed portion 51A and a front surface side recessed portion 51B. The bottom surface side recessed portion 51A is recessed from the bottom surface 50A toward the front surface 50B at the center in the X direction of the gate electrode 50. That is, the bottom surface side recessed portion 51A is open toward the field plate electrode 52. The front surface side recessed portion 51B is recessed from the front surface 50B toward the bottom surface 50A at the center in the X direction of the gate electrode 50. The gate electrode 50 may have a width decreasing from the front surface 50B toward the bottom surface 50A as illustrated in FIG. 3. In another example, the gate electrode 50 may have a substantially uniform width (dimension in the X direction).

The insulating layer 16 can be placed between the gate electrode 50 and the semiconductor layer 12 and cover the side wall 14A of the gate trench 14. The gate electrode 50 opposes the semiconductor layer 12 in the X direction through the insulating layer 16. That is, the gate electrode 50 is separated from the side wall 14A by the insulating layer 16. When a predetermined voltage is applied to the gate electrode 50, a channel is formed in the p− body region 42 adjacent to the insulating layer 16. The semiconductor apparatus 10 can control a flow of electrons in the Z direction between the n+ source region 44 and the n-drift region 40 through the channel.

The gate electrode 50 is arranged closer to the body region 42 than the drift region 40. In one example, the gate electrode 50 may be positioned such that the bottom surface 50A of the gate electrode 50 is not closer to the bottom wall 14B of the gate trench 14 in the Z direction than the interface 41 of the drift region 40 and the body region 42 is. In one example, the gate electrode 50 may be arranged such that the bottom surface 50A of the gate electrode 50 is at the same position as the interface 41 of the drift region 40 and the body region 42 in the Z direction. In another example, the gate electrode 50 may be arranged such that the bottom surface 50A of the gate electrode 50 is positioned closer to the second surface 12B of the semiconductor layer 12 than the interface 41 of the drift region 40 and the body region 42 is.

The field plate electrode 52 is arranged between the bottom surface 50A of the gate electrode 50 and the bottom wall 14B of the gate trench 14 in the gate trench 14. The potential of the field plate electrode 52 can be the same as the potential of the source region 44. A source voltage can be applied to the field plate electrode 52 to mitigate the electric field concentration in the gate trench 14, and this can improve the withstand voltage of the semiconductor apparatus 10. The field plate electrode 52 is formed in a substantially rectangular shape in which the Z direction is the length direction (longitudinal direction) and the X direction is the width direction (transverse direction) in cross-sectional view of FIG. 3. In the example illustrated in FIG. 3, the field plate electrode 52 is formed in a tapered shape becoming narrower from the opposing surface 52A toward the bottom surface 52B. The gate electrode 50 and the field plate electrode 52 can be formed by, for example, conductive polysilicon.

As illustrated in FIG. 2, the semiconductor apparatus 10 can further include a drain electrode 54 formed on the first surface 12A of the semiconductor layer 12. The drain electrode 54 is electrically connected to the drain region 36. The drain electrode 54 may be formed by a material containing at least one of Ti, Ni, Au, Ag, Cu, Al, Cu alloy, and Al alloy.

### [Structure of Opening Portion of Gate Trench and Around Opening Portion]

A structure of the opening portion of the gate trench 14 and around the opening portion will be described in more detail with reference to FIGS. 3 and 4. See mainly FIG. 4 for the dimensional relation between the constituent elements.

As illustrated in FIG. 3, the body region 42 is formed in, for example, the surface layer region (mesa region 60) of the semiconductor layer 12 in the region between two gate trenches 14 adjacent to each other in the X direction. The body contact region 48 is formed on the body region 42. The body contact region 48 is formed throughout the entire mesa region 60 in the X direction in the second surface 12B of the semiconductor layer 12. Therefore, it can be stated that the body contact region 48 is also formed on the side wall 14A of the gate trench 14. The body contact region 48 is formed on one of the two end portions of the side wall 14A of the gate trench 14 in the Z direction closer to the second surface 12B.

The entire front surface 48A (second surface 12B) of the body contact region 48 is formed as a flat surface without a hole. That is, a hole extending in the Z direction from the front surface 48A (second surface 12B) of the body contact region 48 is not provided in the mesa region 60. It can be stated that the body contact region 48 is formed on the body region 42. In one example, the front surface 48A of the body contact region 48 is formed by a plane (XY plane) orthogonal to the Z direction. A depth dimension H2 of the body contact region 48 is smaller than a depth dimension H1 of the body region 42. The depth dimension H2 is equal to or smaller than 1/5 of the depth dimension H1.

The source region 44 is formed along part of the side wall 14A of the gate trench 14. That is, the source region 44 is formed at a position overlapping the body contact region 48 in plan view. The source region 44 is in contact with both the body region 42 and the body contact region 48. It can also be stated that the source region 44 is formed in the mesa region 60.

A width dimension W1 of the source region 44 is smaller than ½ of a width dimension W2 of the body contact region 48. In one example, the width dimension W1 is equal to or smaller than ¼ of the width dimension W2. In one example, the width dimension W1 is equal to or greater than 1/10 of the width dimension W2. The width dimension W1 of the source region 44 is smaller than a depth dimension H3 of the source region 44. In the embodiment, the body contact region 48 is formed throughout the entire mesa region 60 in the X direction, and the width dimension W2 of the body contact region 48 is equal to the width dimension of the mesa region 60. Therefore, it can also be stated that the width dimension W1 of the source region 44 is smaller than ½ of the width dimension of the mesa region 60.

The source region 44 includes a source contact region 46 that is in contact with the source wiring 28. The source contact region 46 is a region of the source region 44 exposed from the insulating layer 16. The source contact region 46 is formed on one of the two end portions of the source region 44 in the Z direction closer to the second surface 12B. Therefore, the source contact region 46 is in contact with the body contact region 48 in the Z direction. The source contact region 46 is also in contact with the body region 42 in the X direction. A depth dimension H4 of the source contact region 46 is equal to or smaller than ½ of the depth dimension H3 of the source region 44.

The gate electrode 50 is arranged closer to the bottom wall 14B of the gate trench 14 in the Z direction than the body contact region 48 is. In one example, the front surface 50B of the gate electrode 50 is positioned closer to the bottom wall 14B than the body contact region 48 is. That is, the front surface 50B of the gate electrode 50 is arranged at a position separated from the body contact region 48 in the Z direction.

The front surface 50B of the gate electrode 50 may be arranged at the same position as a lower edge of the source region 44 in the Z direction. The lower edge of the source region 44 is an edge of the source region 44 in the Z direction farthest from the body contact region 48. It can also be stated that the lower edge of the source region 44 is one of the two edges of the source region 44 in the Z direction closer to the bottom wall 14B of the gate trench 14. Note that the front surface 50B of the gate electrode 50 may be closer to the bottom wall 14B or closer to the second surface 12B in the Z direction than the lower edge of the source region 44 is.

The insulating layer 16 includes a first insulating layer 56 that covers the side surface 50C of the gate electrode 50 and a region between the gate electrode 50 and the bottom wall 14B of the gate trench 14, and a second insulating layer 58 formed on the gate electrode 50. The first insulating layer 56 and the second insulating layer 58 are integrated in such a manner as to surround the gate electrode 50. The first insulating layer 56 and the second insulating layer 58 may be formed by the same insulating material or may be formed by different insulating materials. The first insulating layer 56 and the second insulating layer 58 may be formed by, for example, an insulating material containing silicon oxide (SiO) or silicon nitride (SiN). In one example, both the first insulating layer 56 and the second insulating layer 58 are formed by SiO₂ films.

The second insulating layer 58 covers the front surface 50B of the gate electrode 50. The second insulating layer 58 is in contact with part of the front surface 50B of the gate electrode 50 and the side wall 14A of the gate trench 14 in the Z direction. The second insulating layer 58 includes a front surface 58A on the opposite side of the gate electrode 50. The front surface 58A is arranged closer to the gate electrode 50 than the front surface 48A (second surface 12B) of the body contact region 48 is. The front surface 58A is arranged at the same position as the lower edge of the source contact region 46 in the Z direction. That is, the second insulating layer 58 covers part of the source region 44, but does not cover the source contact region 46. Therefore, the source contact region 46 is exposed from the insulating layer 16. It can be stated that the source contact region 46 is a region of the source region 44 protruding from the front surface 58A of the second insulating layer 58 toward the second surface 12B in the Z direction. The body contact region 48 is not covered by the insulating layer 16. That is, the body contact region 48 is exposed from the insulating layer 16.

In the cross section illustrated in FIG. 3, the source wiring 28 is formed on the insulating layer 16. The source wiring 28 is arranged across both the gate trench 14 and the body region 42 in plan view. The source wiring 28 is electrically connected to both the source contact region 46 and the body contact region 48.

The source wiring 28 includes a wiring body 28A and a contact plug 28B. In one example, the wiring body 28A and the contact plug 28B are integrated. Note that the wiring body 28A and the contact plug 28B may be formed as separate bodies.

The wiring body 28A is formed on the second surface 12B of the semiconductor layer 12 in the source wiring 28. The wiring body 28A is in contact with the second surface 12B. That is, the wiring body 28A is in contact with the front surface 48A of the body contact region 48. Therefore, the source wiring 28 is electrically connected to the body contact region 48. In one example, the wiring body 28A is in contact with the entire front surface 48A of the body contact region 48. The body contact region 48 corresponds to the p+ region 24, and it can be stated that the source wiring 28 is in contact with the entire front surface of the p+ region 24 of FIG. 1.

The contact plug 28B protrudes from the wiring body 28A toward the inside of each gate trench 14. The contact plug 28B is fitted between the front surface 48A (second surface 12B) of the body contact region 48 and the front surface 58A of the second insulating layer 58 in the gate trench 14. The contact plug 28B is in contact with the part of the side wall 14A of the gate trench 14 closer to the second surface 12B than the front surface 58A of the second insulating layer 58 is. Both the side surface of the source contact region 46 and the side surface of the body contact region 48 are exposed at the part of the side wall 14A of the gate trench 14 closer to the second surface 12B than the front surface 58A of the second insulating layer 58 is. Therefore, the contact plug 28B is in contact with both the side surface of the source contact region 46 and the side surface of the body contact region 48. In this way, the source wiring 28 is electrically connected to both the source contact region 46 (source region 44) and the body contact region 48. The contact plug 28B is in contact with the front surface 58A of the second insulating layer 58.

The side surface of the source contact region 46 here is a surface of the source contact region 46 exposed from the side wall 14A of the gate trench 14. The side surface of the body contact region 48 is a surface of the body contact region 48 exposed from the side wall 14A of the gate trench 14. In one example, the side surface of the source contact region 46 and the side surface of the body contact region 48 are continuously formed in the Z direction. In one example, the side surface of the source contact region 46 and the side surface of the body contact region 48 are formed to be flush with each other.

A thickness dimension (hereinafter, a “thickness dimension TC”) of the contact plug 28B in the Z direction is larger than the depth dimension H2 of the body contact region 48. The thickness dimension TC is smaller than the depth dimension H3 of the source region 44. In one example, the thickness dimension TC is equal to or smaller than ½ of a distance DA between the front surface 48A (second surface 12B) of the body contact region 48 and the gate electrode 50 in the Z direction. In one example, the contact plug 28B is in contact with the entire side surface of the source contact region 46 in the Y direction. Therefore, the dimension in the Y direction of the contact plug 28B is equal to or greater than the dimension in the Y direction of the source contact region 46.

### [Manufacturing Method of Semiconductor Apparatus]

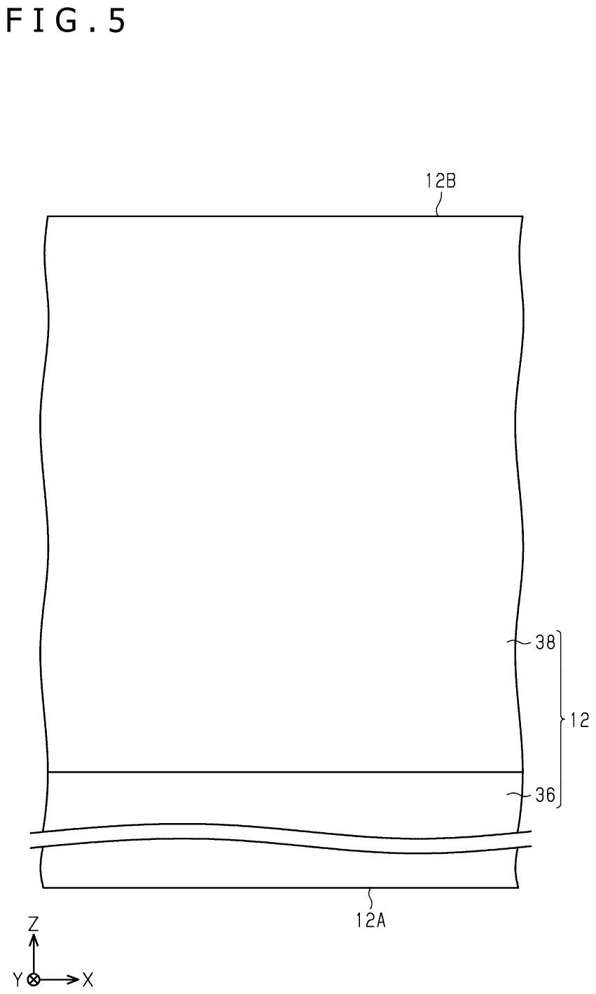

An example of a manufacturing method of the semiconductor apparatus 10 will be described with reference to FIGS. 5 to 19.

FIGS. 5 to 19 are schematic cross-sectional views illustrating an exemplary manufacturing process of the semiconductor apparatus 10. Note that the same reference signs are provided to the constituent elements in FIGS. 5 to 19 similar to the constituent elements in FIGS. 2 to 4 to facilitate the understanding.

As illustrated in FIG. 5, the manufacturing method of the semiconductor apparatus 10 includes forming the epitaxial layer 38 on the semiconductor substrate 36. As a result, the semiconductor layer 12 including the semiconductor substrate 36 and the epitaxial layer 38 is formed. The semiconductor substrate 36 may be a Si substrate containing n-type impurities. The epitaxial layer 38 may be an n-Si layer doped with n-type impurities and epitaxially grown on the semiconductor substrate 36.

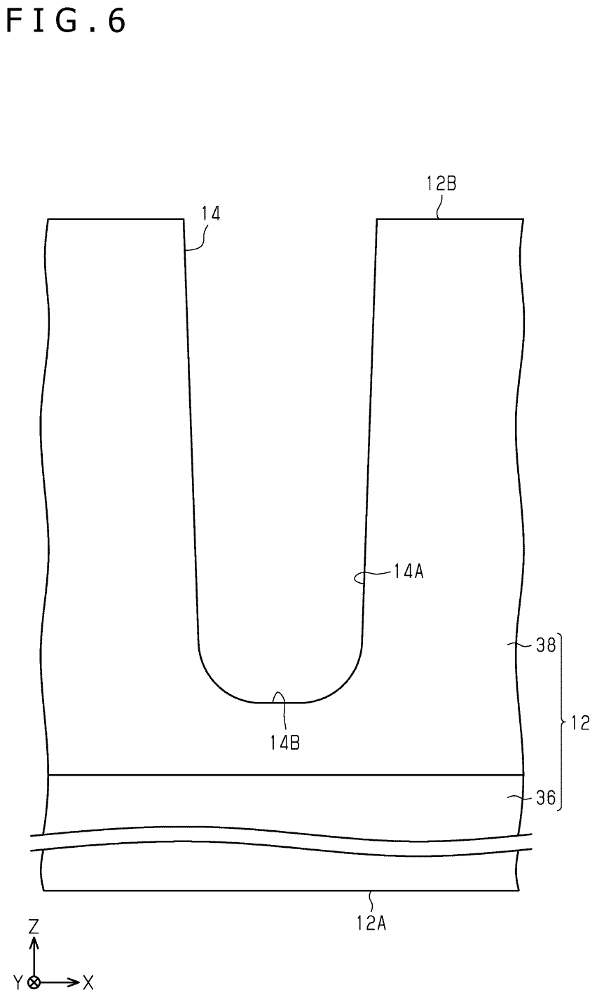

As illustrated in FIG. 6, the manufacturing method of the semiconductor apparatus 10 includes forming, in the semiconductor layer 12, the gate trench 14 including the side wall 14A and the bottom wall 14B. In the process, part of the epitaxial layer 38 is selectively removed by etching with a mask (not illustrated) in a predetermined pattern formed on the second surface 12B of the semiconductor layer 12. In this way, the gate trench 14 including an opening on the second surface 12B of the semiconductor layer 12 can be formed. The gate trench 14 is extended along the Y direction in plan view.

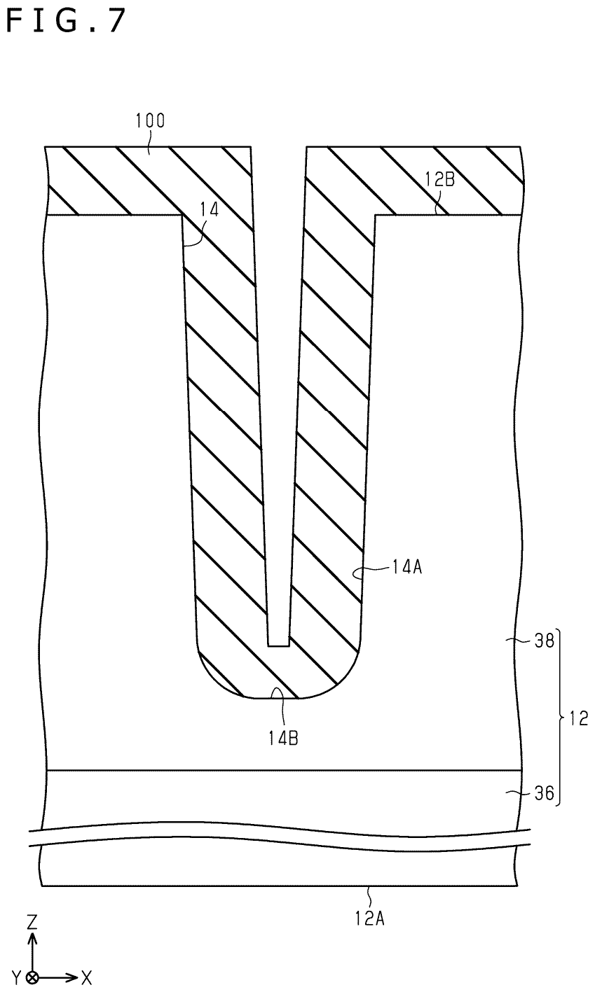

As illustrated in FIG. 7, the manufacturing method of the semiconductor apparatus 10 includes forming a first insulating layer 100 on the semiconductor layer 12. The first insulating layer 100 is an insulating layer that is part of the first insulating layer 56 (see FIG. 3) of the insulating layer 16. The first insulating layer 100 can be formed along the second surface 12B of the semiconductor layer 12 and the side wall 14A and the bottom wall 14B of the gate trench 14. In one example, the first insulating layer 100 may be SiO₂ formed by a thermal oxidation method. In another example, the first insulating layer 100 may be SiO₂ formed by a chemical vapor deposition (CVD) method. In this way, the first insulating layer 100 may be a SiO₂ film.

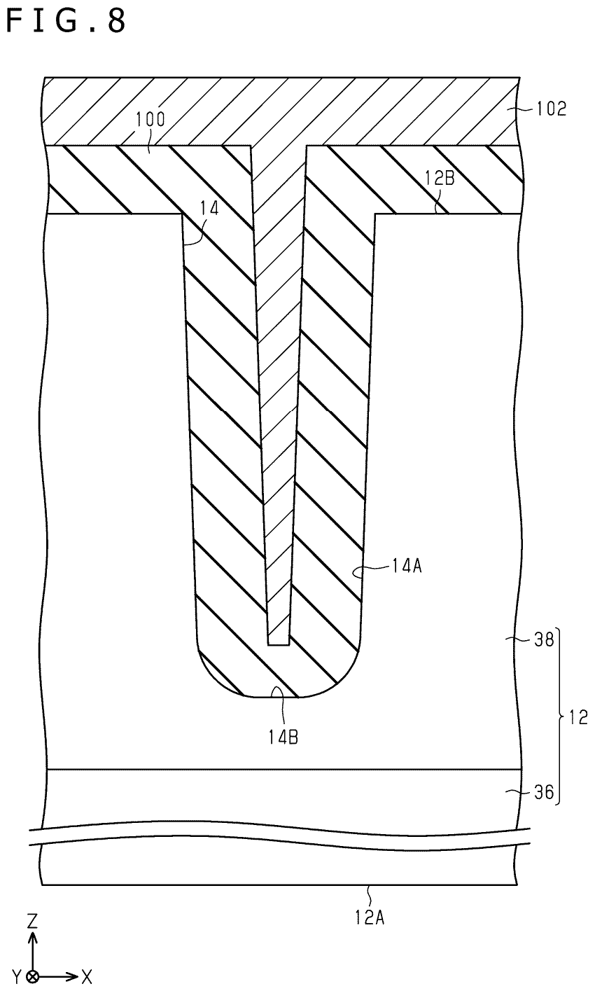

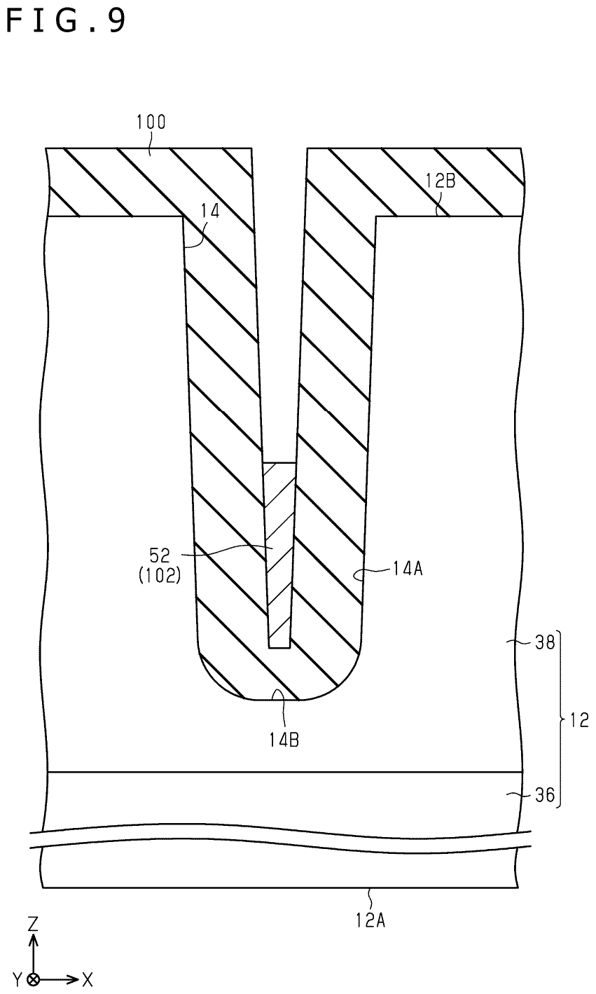

As illustrated in FIGS. 8 and 9, the manufacturing method of the semiconductor apparatus 10 includes forming the field plate electrode 52 (see FIG. 9) in the gate trench 14.

As illustrated in FIG. 8, forming the field plate electrode 52 in the gate trench 14 includes forming a first conductive layer 102 on the first insulating layer 100. Part of the first conductive layer 102 is implanted into a recessed space formed in the gate trench 14. In this way, the gate trench 14 can be filled with the first insulating layer 100 and the first conductive layer 102. The first conductive layer 102 may be, for example, conductive polysilicon. The first conductive layer 102 can be formed by, for example, sputtering.

As illustrated in FIG. 9, forming the field plate electrode 52 in the gate trench 14 includes removing part of the first conductive layer 102 by etching. In the process, the first conductive layer 102 can be etched to expose the first insulating layer 100 covering the second surface 12B of the semiconductor layer 12, and the upper surface of the first conductive layer 102 in the gate trench 14 can be positioned in the middle of the gate trench 14 in the depth direction (Z direction). The field plate electrode 52 is formed through the process described above.

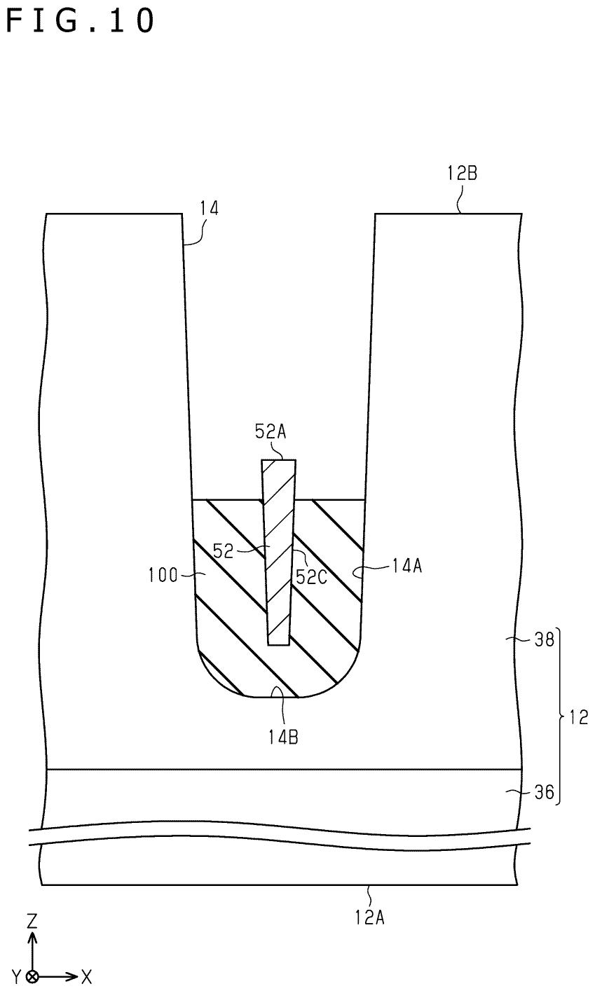

As illustrated in FIG. 10, the manufacturing method of the semiconductor apparatus 10 includes removing part of the first insulating layer 100 by etching. In the process, the part of the first insulating layer 100 formed closer to the second surface 12B of the semiconductor layer 12 in the part closer to the opposing surface 52A than the center in the Z direction of the field plate electrode 52 in the gate trench 14 and the part formed on the second surface 12B of the semiconductor layer 12 can be etched. As a result, the side surface 52C of the part closer to the opposing surface 52A than the center in the Z direction of the field plate electrode 52 and the opposing surface 52A can be exposed. Part of the side wall 14A of the gate trench 14 and the second surface 12B of the semiconductor layer 12 can also be exposed.

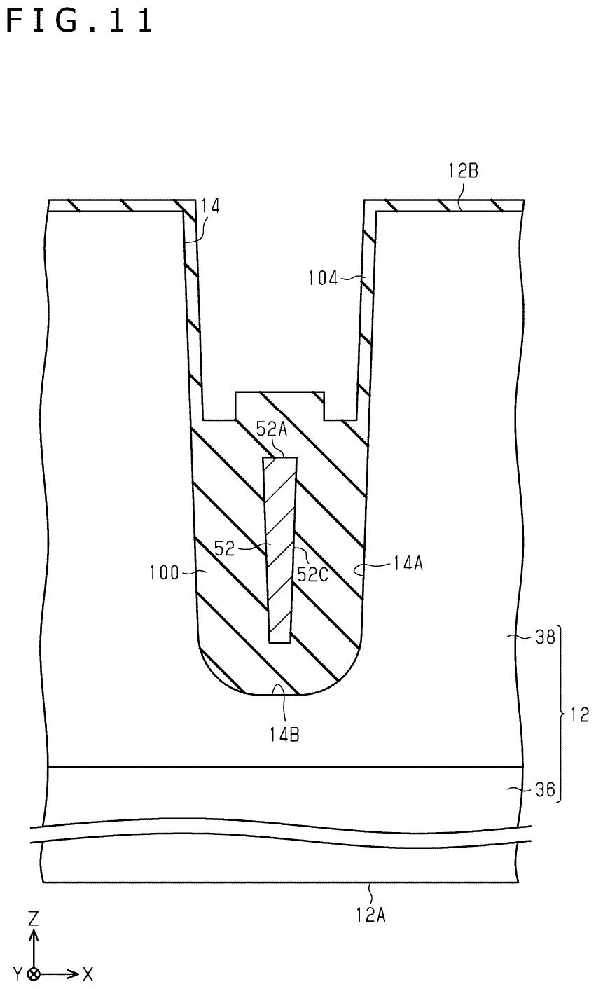

As illustrated in FIG. 11, the manufacturing method of the semiconductor apparatus 10 includes forming a second insulating layer 104 on the semiconductor layer 12. The second insulating layer 104 can be formed along the exposed part of the field plate electrode 52, the exposed part of the side wall 14A of the gate trench 14, and the second surface 12B of the semiconductor layer 12. The second insulating layer 104 is an insulating layer that is part of the first insulating layer 56 of the insulating layer 16. In one example, the second insulating layer 104 may be SiO₂ formed by the thermal oxidation method. In another example, the second insulating layer 104 may be SiO₂ formed by the CVD method. In this way, the second insulating layer 104 may be a SiO₂ film. The second insulating layer 104 can be formed in a relatively thin thickness. In one example, the second insulating layer 104 may be formed in a thickness thinner than the first insulating layer 100.

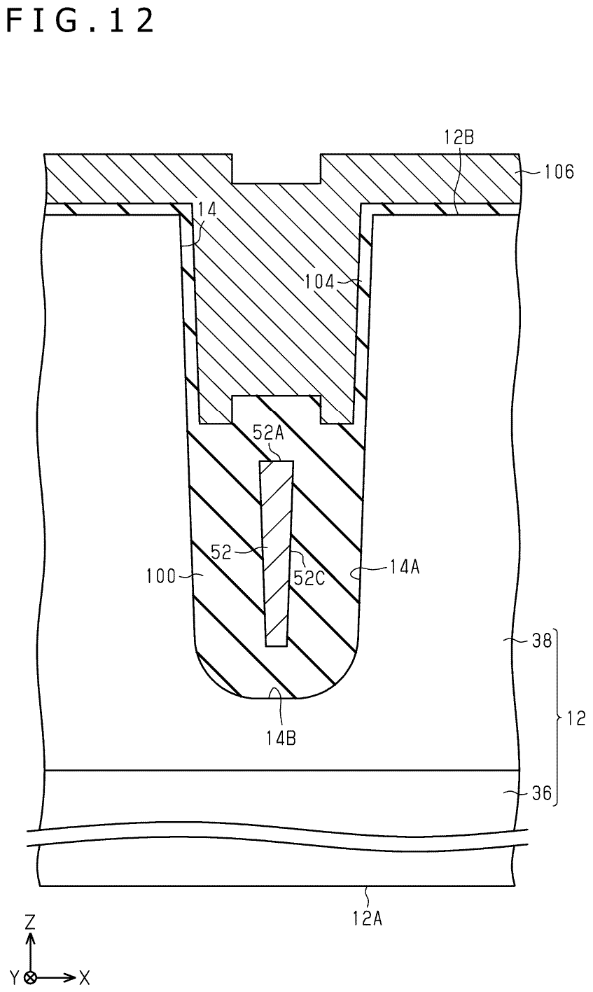

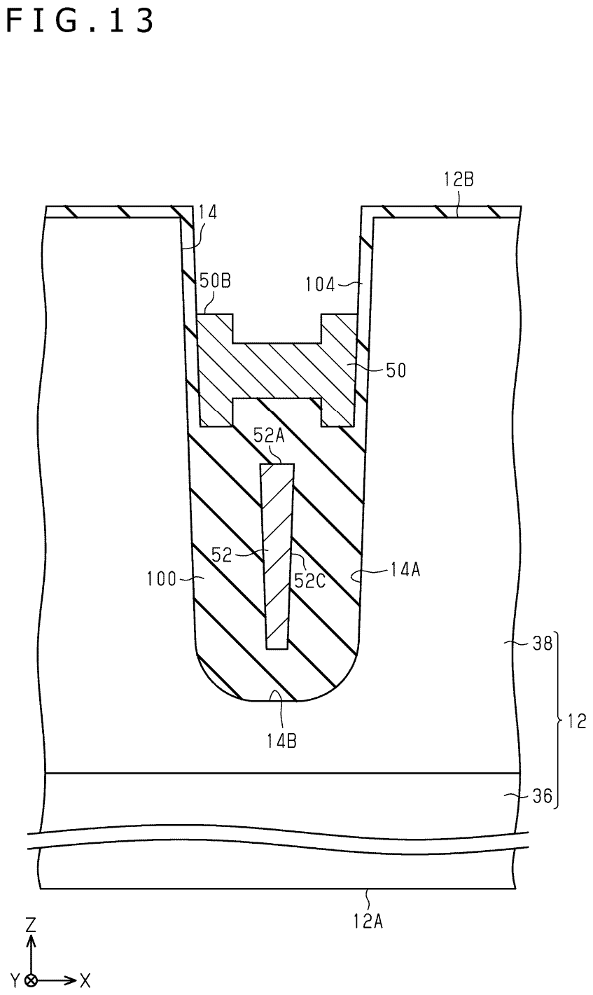

As illustrated in FIGS. 12 and 13, the manufacturing method of the semiconductor apparatus 10 includes forming the gate electrode 50 in the gate trench 14.

As illustrated in FIG. 12, forming the gate electrode 50 in the gate trench 14 includes forming a second conductive layer 106 on the second insulating layer 104. Part of the second conductive layer 106 is implanted into the recessed space formed in the gate trench 14. Part of the second conductive layer 106 can be formed on the second insulating layer 104 covering the second surface 12B of the semiconductor layer 12. The second conductive layer 106 may be, for example, conductive polysilicon. The second conductive layer 106 can be formed by, for example, sputtering.

As illustrated in FIG. 13, forming the gate electrode 50 in the gate trench 14 includes removing part of the second conductive layer 106 by etching. In the process, the second conductive layer 106 is etched to expose the second insulating layer 104 covering the second surface 12B of the semiconductor layer 12. The gate electrode 50 is formed through the process described above. The front surface 50B of the gate electrode 50 is positioned closer to the bottom wall 14B of the gate trench 14 than the second surface 12B is.

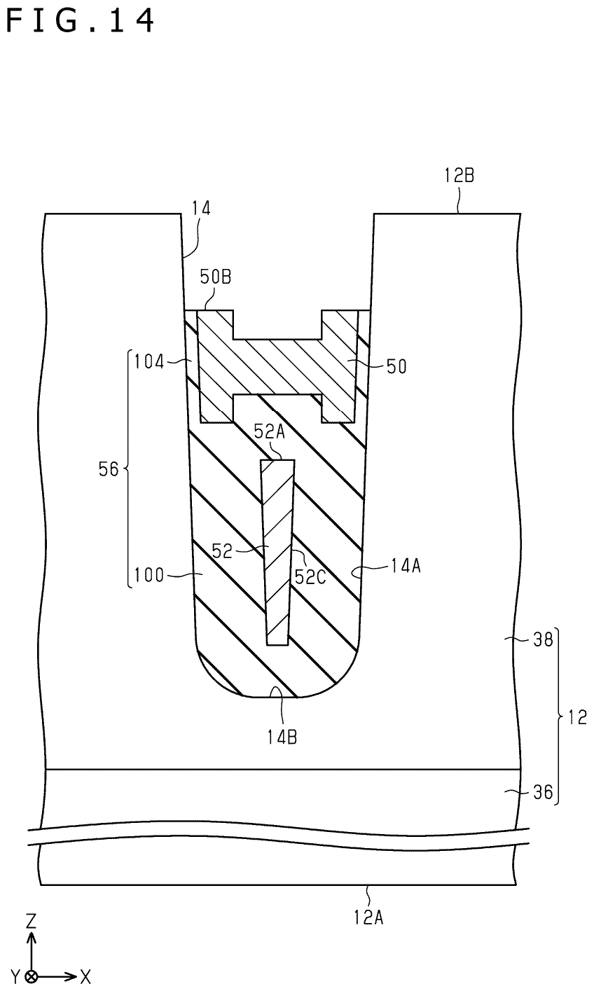

As illustrated in FIG. 14, the manufacturing method of the semiconductor apparatus 10 includes removing part of the second insulating layer 104 by etching. In the process, the part of the second insulating layer 104 closer to the second surface 12B than the front surface 50B of the gate electrode 50 and the part on the second surface 12B can be etched. As a result, the part of the side wall 14A of the gate trench 14 closer to the second surface 12B than the front surface 50B of the gate electrode 50 and the second surface 12B can be exposed. The first insulating layer 56 of the insulating layer 16 is formed through the process.

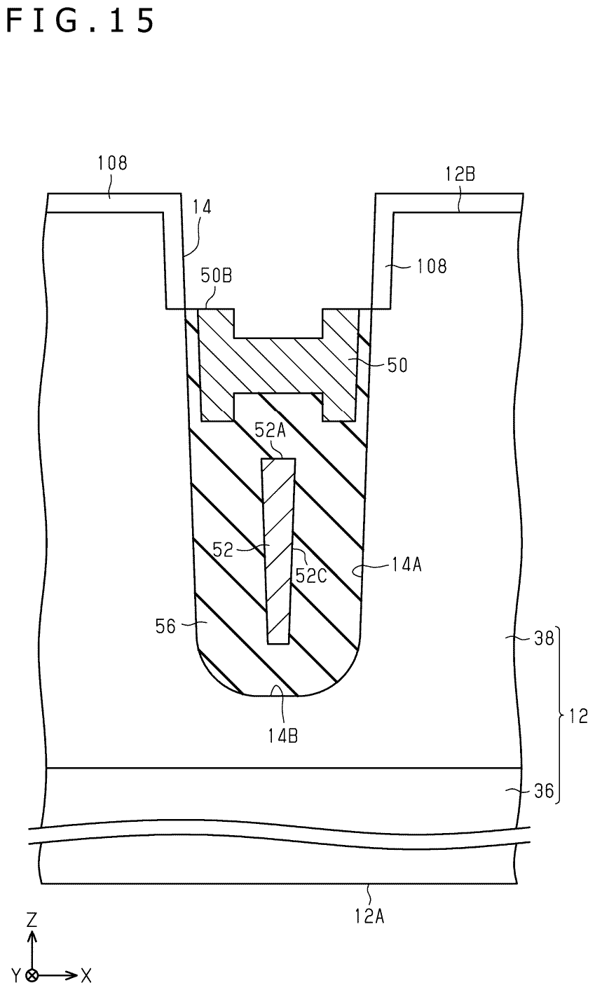

As illustrated in FIG. 15, the manufacturing method of the semiconductor apparatus 10 includes forming a source formation region 108 in the epitaxial layer 38. The source formation region 108 is formed in a region in the gate trench 14 exposed from the second insulating layer 104 and on the second surface 12B of the semiconductor layer 12. The source formation region 108 is an n+ region. In the process, ion implantation is used to implant n-type impurities into the region exposed from the second insulating layer 104 in the gate trench 14, which is the front surface of the epitaxial layer 38 that is an n-type Si layer, and into the second surface 12B.

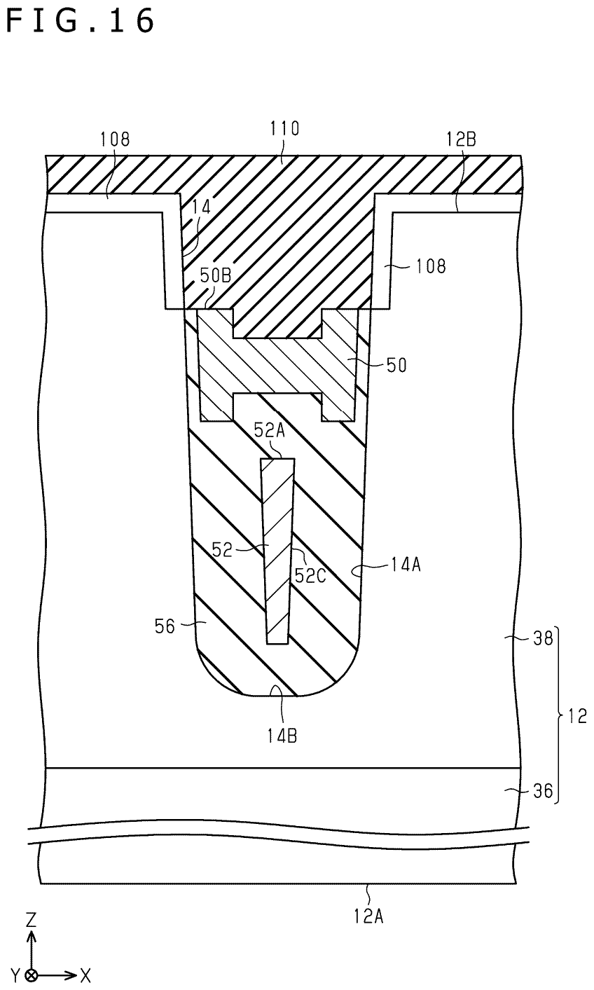

As illustrated in FIG. 16, the manufacturing method of the semiconductor apparatus 10 includes forming a third insulating layer 110 in the gate trench 14 and on the second surface 12B. The third insulating layer 110 is an insulating layer included in the second insulating layer 58 (see FIG. 3) of the insulating layer 16. The third insulating layer 110 covers the source formation region 108. In one example, the second insulating layer 104 may be SiO₂ formed by the CVD method. In another example, the second insulating layer 104 may be SiO₂ formed by the thermal oxidation method. In this way, the second insulating layer 104 may be a SiO₂ film.

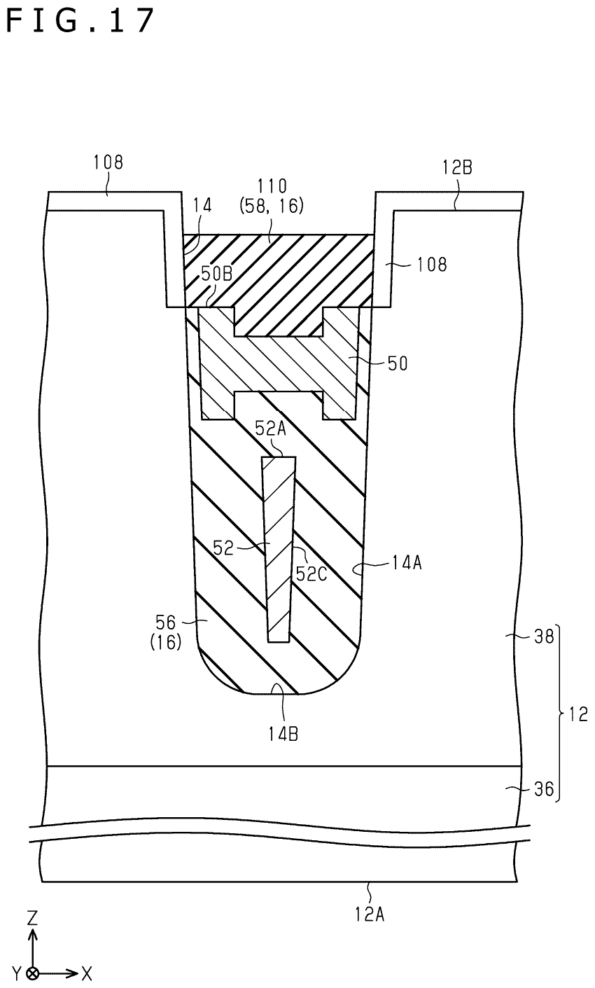

As illustrated in FIG. 17, the manufacturing method of the semiconductor apparatus 10 includes removing part of the third insulating layer 110 by etching. In the process, the part of the third insulating layer 110 on the second surface 12B and the part provided on an opening end portion of the gate trench 14 can be etched. The second insulating layer 58 of the insulating layer 16 is formed through the process.

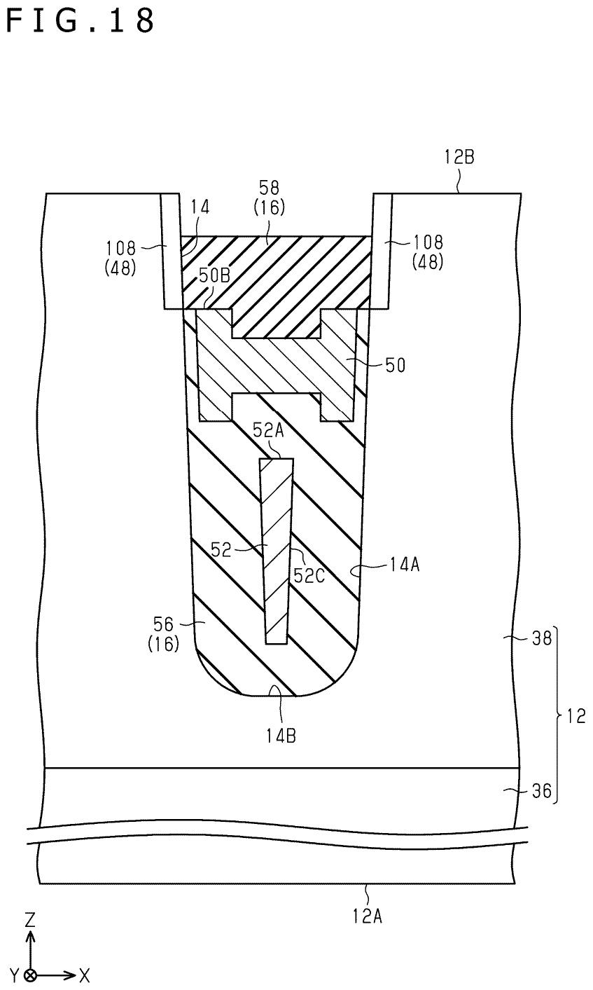

As illustrated in FIG. 18, the manufacturing method of the semiconductor apparatus 10 includes a process of grinding the second surface 12B of the semiconductor layer 12. In the process, the second surface 12B can be polished by, for example, chemical mechanical polishing (CMP). As a result, the source formation region 108 formed on the second surface 12B is removed. In this way, the region in the gate trench 14 exposed from the second insulating layer 104 remains as the source formation region 108.

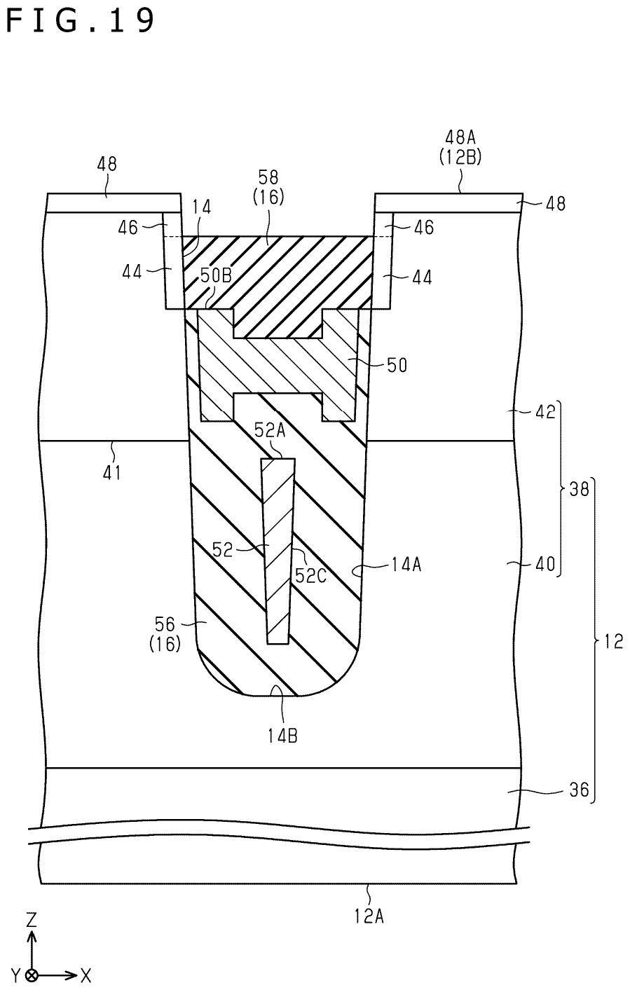

As illustrated in FIG. 19, the manufacturing method of the semiconductor apparatus 10 includes forming the body region 42 and forming the body contact region 48. Ion implantation is used to implant p-type impurities into the surface layer region of the epitaxial layer 38. In this way, the body region 42 is formed. The p-type impurities are further implanted into the second surface 12B. In this way, the body contact region 48 is formed.

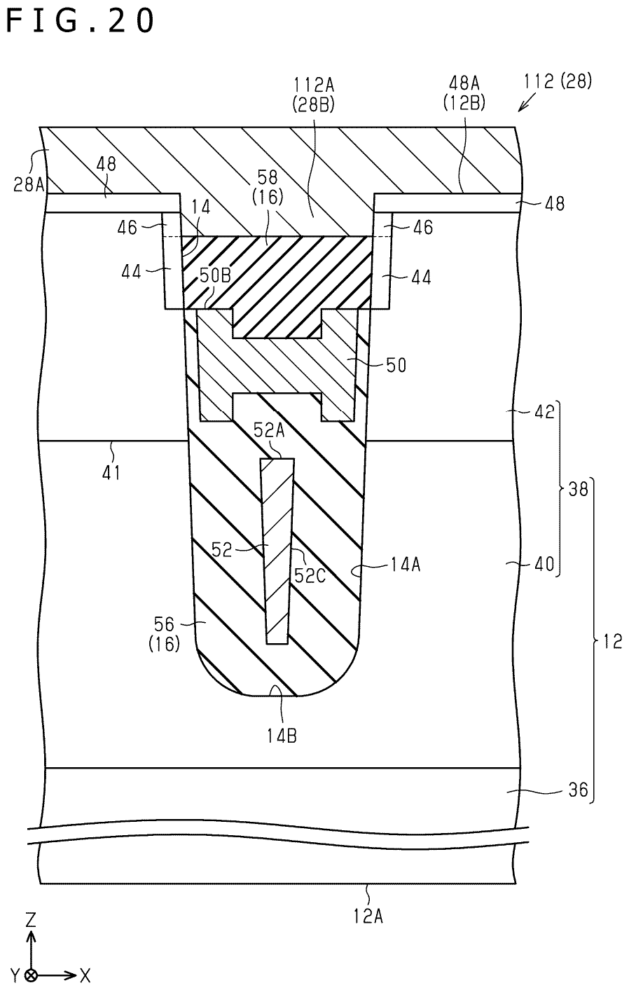

As illustrated in FIG. 20, the manufacturing method of the semiconductor apparatus 10 includes forming the source wiring 28. In the process, a third conductive layer 112 is formed on the second surface 12B of the semiconductor layer 12 and in the gate trench 14 by, for example, sputtering. An implanted portion 112A of the third conductive layer 112 implanted into the gate trench 14 is included in the contact plug 28B of the source wiring 28. The third conductive layer 112 is then patterned to form the wiring body 28A from the third conductive layer 112. The source wiring 28 is formed through the process.

Although not illustrated, the manufacturing method of the semiconductor apparatus 10 includes forming the drain electrode 54 (see FIG. 2). The semiconductor apparatus 10 is manufactured through the process. Although the manufacturing method of the semiconductor apparatus 10 includes a plurality of sequentially executed manufacturing processes in the description above, it should be understood that some of the manufacturing processes may be executed in parallel or may be executed in a different order. Some of the manufacturing processes may be eliminated, and a process different from the example may be executed in one of the manufacturing processes.

### [Action]

An action of the semiconductor apparatus 10 of the embodiment will be described.

There is a generally known configuration (hereinafter, a “comparative configuration”) of electrically connecting the body region and the source wiring to each other by, for example, implanting part of the source wiring into a contact hole in the mesa region for contacting the body region. In the comparative configuration, a body contact region is formed on a bottom portion of the contact hole.

The contact hole is formed in the mesa region in the comparative configuration, and it is difficult to reduce the dimension in the X direction of the mesa region. In addition, the positions of the upper surface of the gate electrode and the bottom portion of the contact hole in the Z direction need to be adjusted in the comparative configuration. The gate electrode and the contact hole are separately formed by etching. Therefore, high processing accuracy is necessary in the etching of the gate electrode and the contact hole.

In the semiconductor apparatus 10 of the embodiment, the source wiring 28 is formed in contact with the source contact region 46 formed on the side wall 14A of the gate trench 14 and in contact with the body contact region 48 formed on the second surface 12B. Therefore, the contact hole is not formed in the mesa region 60. This can reduce the dimension in the X direction of the mesa region 60. That is, the distance between the gate trenches 14 adjacent to each other in the X direction can be reduced. In addition, the formation of the contact hole of the mesa region 60 and the adjustment of the positions of the upper surface of the gate electrode and the bottom portion of the contact hole in the Z direction are unnecessary. Therefore, high processing accuracy is unnecessary in the etching.

### [Effects]

According to the semiconductor apparatus 10 of the embodiment, the following effects can be obtained.

(1) The semiconductor apparatus 10 includes the drift region 40, the body region 42 formed on the drift region 40, the body contact region 48 formed on the body region 42, the gate trench 14 formed to penetrate both the body region 42 and the body contact region 48 and reach the drift region 40, the gate trench 14 including the side wall 14A and the bottom wall 14B, the insulating layer 16 formed in the gate trench 14, the gate electrode 50 arranged in the gate trench 14 and separated from the side wall 14A by the insulating layer 16, the source region 44 formed along part of the side wall 14A, the source region 44 being in contact with both the body region 42 and the body contact region 48, and the source wiring 28 arranged across both the gate trench 14 and the body region 42 in plan view. The source region 44 includes the source contact region 46 that is in contact with the source wiring 28. The source wiring 28 is in contact with both the side surface of the source contact region 46 and the front surface 48A of the body contact region 48.

According to this configuration, the body contact region 48 is formed on the body region 42. The source region 44 including the source contact region 46 is formed on the side wall 14A of the gate trench 14. The source wiring 28 is in contact with both the side surface of the source contact region 46 and the front surface 48A of the body contact region 48. Therefore, the contact hole for connecting the body region and the source wiring to each other does not have to be formed in the body region 42. This can downsize the semiconductor apparatus 10 as the contact hole is not formed.

(2) The entire front surface 48A (second surface 12B) of the body contact region 48 is formed as a flat surface without a hole.

According to this configuration, the front surface 48A of the body contact region 48 and the source wiring 28 easily come into surface contact with each other.

(3) The source region 44 is formed to overlap the body contact region 48 in plan view.

According to this configuration, the source region 44 and the body contact region 48 are lined up in the X direction, and the semiconductor apparatus 10 can be downsized in the X direction compared to a configuration in which the body contact region 48 and the source region 44 do not overlap in plan view.

(4) The gate electrode 50 is arranged closer to the bottom wall 14B of the gate trench 14 in the Z direction than the body contact region 48 is. The source region 44 is formed between the body contact region 48 and the gate electrode 50 in the Z direction.

According to this configuration, the source region 44 is arranged closer to the body contact region 48 than the gate electrode 50 is. That is, the gate electrode 50 and the source region 44 do not face each other in the X direction. This can suppress the reduction in the withstand voltage of the gate electrode 50 and the source region 44.

(5) One of the edges of the source region 44 closer to the bottom wall 14B of the gate trench 14 is positioned at the same position as the front surface (front surface 50B) of the gate electrode 50 in the Z direction.

According to this configuration, the channel is also formed on one of the two edges of the source region 44 closer to the bottom wall 14B of the gate trench 14 when the gate voltage is applied to the gate electrode 50. As a result, the drain current easily flows to the source region 44.

(6) The source contact region 46 is formed at the position of the source region 44 adjacent to the body contact region 48 in the Z direction.

According to this configuration, the distance between the source wiring 28 and the gate electrode 50 in the Z direction can be reserved. This can suppress the reduction in the withstand voltage between the source wiring 28 and the gate electrode 50.

(7) The insulating layer 16 includes the first insulating layer 56 that covers the side surface 50C of the gate electrode 50 and the region between the gate electrode 50 and the bottom wall 14B of the gate trench 14, and the second insulating layer 58 formed on the gate electrode 50. The front surface 58A of the second insulating layer 58 is arranged closer to the gate electrode 50 than the front surface 48A (second surface 12B) of the body contact region 48 is. The source wiring 28 is fitted between the front surface 48A (second surface 12B) of the body contact region 48 and the front surface 58A of the second insulating layer 58 in the gate trench 14. The source wiring 28 includes the contact plug 28B that is in contact with the source contact region 46.

According to this configuration, the source wiring 28 is in contact with both the front surface 48A of the body contact region 48 and the side surface exposed from the side wall 14A of the gate trench 14. This can increase the contact area of the source wiring 28 and the body contact region 48.

(8) The thickness dimension TC of the contact plug 28B in the Z direction is larger than the depth dimension H2 of the body contact region 48 in the Z direction.

According to this configuration, the region in which the contact plug 28B and the source contact region 46 face each other in the X direction can be formed. Therefore, the contact plug 28B and the source contact region 46 easily come into contact with each other.

(9) The thickness dimension TC of the contact plug 28B in the Z direction is smaller than the depth dimension H3 of the source region 44 in the Z direction.

According to this configuration, the distance between the contact plug 28B and the gate electrode 50 in the Z direction can be reserved. This can suppress the reduction in the withstand voltage between the source wiring 28 and the gate electrode 50.

(10) The thickness dimension TC of the contact plug 28B in the Z direction is equal to or smaller than ½ of the distance DA between the front surface 48A (second surface 12B) of the body contact region 48 and the gate electrode 50 in the Z direction.

According to this configuration, the distance between the contact plug 28B and the gate electrode 50 in the Z direction can be reserved. This can suppress the reduction in the withstand voltage between the source wiring 28 and the gate electrode 50.

(11) The semiconductor apparatus 10 includes the field plate electrode 52 arranged closer to the bottom wall 14B in the gate trench 14 than the gate electrode 50 is, the field plate electrode 52 being separated from the gate electrode 50, the side wall 14A, and the bottom wall 14B by the insulating layer 16.

According to this configuration, the withstand voltage can be maintained even when the impurity concentration in the epitaxial layer 38 is increased to reduce the on-resistance of the semiconductor apparatus 10. In addition, the gate-drain capacitance can be reduced, and the switching speed of the semiconductor apparatus 10 can be improved.

### <Change Examples>

The embodiment can be changed and carried out as follows. The following change examples can be combined with each other as long as there is no technical contradiction.

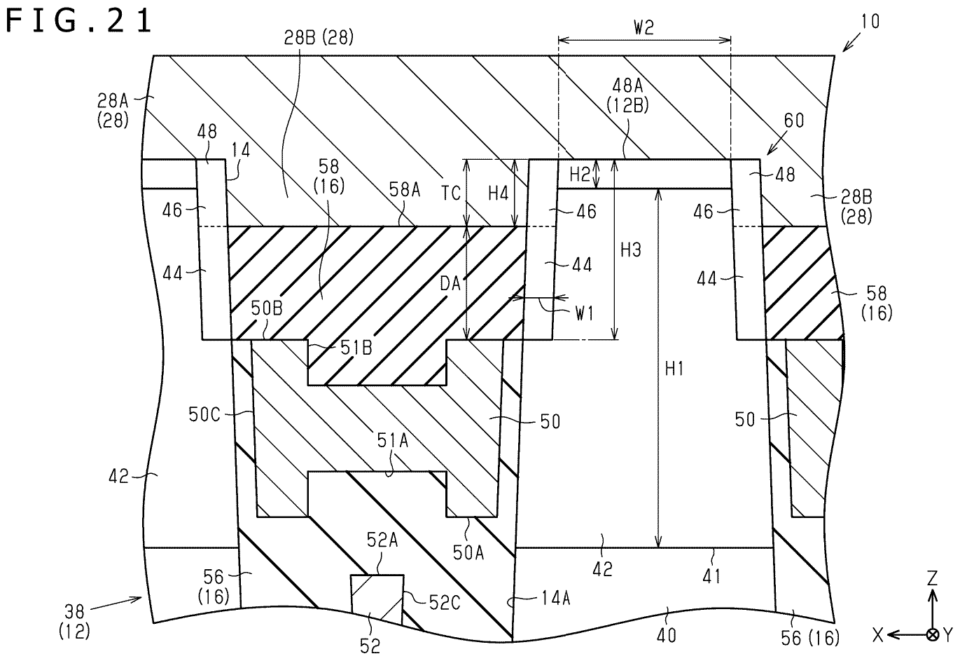

The positional relation between the source region 44 and the body contact region 48 can be changed as desired. In one example, the body contact region 48 may be formed between two source regions 44 separated in the X direction as illustrated in FIG. 21. In this case, the body contact region 48 is in contact with the source regions 44 in the X direction. That is, the body contact region 48 is not exposed from the side wall 14A of the gate trench 14. Therefore, the width dimension W1 of the body contact region 48 is smaller than the width dimension of the mesa region 60. The thickness dimension TC of the contact plug 28B of the source wiring 28 is equal to the depth dimension H4 of the source contact region 46.

In the example illustrated in FIG. 21, the depth dimension H4 of the source contact region 46 is larger than the depth dimension H2 of the body contact region 48. The depth dimension H4 is, for example, equal to or more than twice the depth dimension H2. It can also be stated that the thickness dimension TC of the contact plug 28B is equal to or more than twice the depth dimension H2.

Note that, in the change example illustrated in FIG. 21, the position in the Z direction of the front surface 58A of the second insulating layer 58 can be changed as desired on condition that the position is closer to the gate electrode 50 than the second surface 12B of the semiconductor layer 12 is. In one example, the front surface 58A may be at the same position as the interface of the body contact region 48 and the body region 42 in the Z direction. That is, the thickness of the second insulating layer 58 may be thicker than that in the example illustrated in FIG. 21. Accordingly, the depth dimension H4 of the source contact region 46 is reduced. The depth dimension H4 may be equal to the depth dimension H2 of the body contact region 48.

The position of the gate electrode 50 in the Z direction can be changed as desired. In one example, the front surface 50B of the gate electrode 50 may be arranged closer to the bottom wall 14B of the gate trench 14 in the Z direction than the source region 44 is.

The relation between the width dimension W1 and the depth dimension H3 of the source region 44 can be changed as desired. In one example, the width dimension W1 may be equal to the depth dimension H3. In one example, the width dimension W1 may be larger than the depth dimension H3.

The relation between the width dimension W1 of the source region 44 and the width dimension W2 of the body contact region 48 can be changed as desired. In one example, the width dimension W1 may be equal to or greater than ½ of the width dimension W2. In one example, the width dimension W1 may be equal to or greater than the width dimension W2. In this case, the body contact region 48 is formed in part of the mesa region 60 in the X direction.

The thickness dimension TC of the contact plug 28B of the source wiring 28 can be changed as desired. In one example, the thickness dimension TC may be equal to the depth dimension H3 of the source region 44. In one example, the thickness dimension TC may be larger than the depth dimension H3. The thickness dimension TC may be larger than ½ of the distance DA between the front surface 48A (second surface 12B) of the body contact region 48 and the gate electrode 50. In one example, the thickness dimension TC of the contact plug 28B of the source wiring 28 may be equal to the depth dimension H2 of the body contact region 48. The thickness dimension TC may be smaller than the depth dimension H2.

The cross-sectional shape of the gate electrode 50 cut along the XZ plane can be changed as desired. In one example, at least one of the bottom surface side recessed portion 51A and the front surface side recessed portion 51B may be eliminated from the gate electrode 50. When the bottom surface side recessed portion 51A is eliminated from the gate electrode 50, the bottom surface 50A of the gate electrode 50 may be flat or may be curved. When the front surface side recessed portion 51B is eliminated from the gate electrode 50, the front surface 50B of the gate electrode 50 may be flat or may be curved.

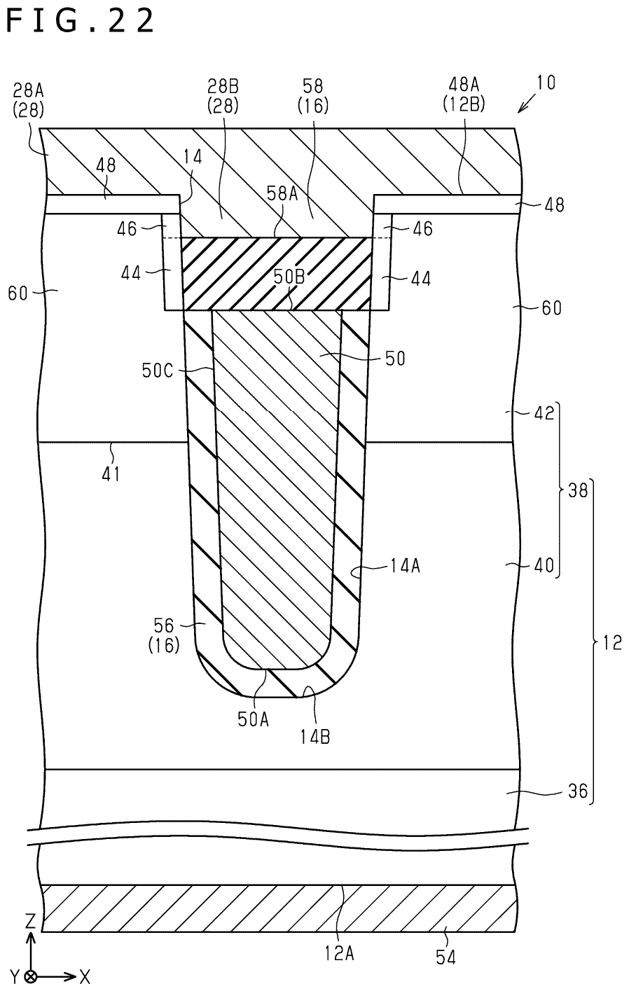

The field plate electrode 52 may be eliminated from the semiconductor apparatus 10. In this case, the gate electrode 50 may be extended in the Z direction as illustrated in FIG. 22. The first insulating layer 56 is formed to cover the side surface 50C and the bottom surface 50A of the gate electrode 50. In one example, the front end surface of the first insulating layer 56 is flush with the front surface 50B of the gate electrode 50. In one example, the thickness of the first insulating layer 56 is constant. The second insulating layer 58 is formed to cover both the front surface 50B of the gate electrode 50 and the front end surface of the first insulating layer 56. In this way, the insulating layer 16 covers the gate electrode 50.

In the example illustrated in FIG. 22, the body region 42, the source region 44, the source contact region 46, and the body contact region 48 are the same as those in the first embodiment. In one example, one of the two edges of the source region 44 in the Z direction closer to the bottom wall 14B of the gate trench 14 is positioned at the same position as the front surface 50B of the gate electrode 50. The contact plug 28B of the source wiring 28 is in contact with the source contact region 46 in the X direction. According to the change example illustrated in FIG. 22, effects similar to the effects of (1-1) to (1-10) of the embodiment can be obtained. Note that the body region 42, the source region 44, the source contact region 46, and the body contact region 48 may be changed as in the change example illustrated in FIG. 21.

The semiconductor layer 12 may be formed by, for example, silicon carbide (SiC) instead of Si. In this case, the semiconductor substrate 36 of the semiconductor layer 12 may be, for example, a SiC substrate. The epitaxial layer 38 may be a SiC layer epitaxially grown on the SiC substrate.

One or a plurality of various examples described in the present specification can be combined as long as there is no technical contradiction.

It should be understood that “at least one of A and B” in the present specification means “only A, only B, or both A and B.”

The term “on” used in the present disclosure includes meanings of “on” and “above” unless the context clearly indicates otherwise. Therefore, an expression “a first element is arranged on a second element” is intended to indicate that the first element can be directly arranged on the second element in contact with the second element in one embodiment and that the first element can be arranged above the second element without being in contact with the second element in another embodiment. That is, the term “on” does not exclude a structure in which another element is formed between the first element and the second element.

The Z-axis direction used in the present disclosure may not be the vertical direction and may not completely coincide with the vertical direction. Therefore, “up” and “down” in the Z-axis direction described in the present specification are not limited to “up” and “down” in the vertical direction in various structures according to the present disclosure. For example, the X-axis direction may be the vertical direction, or the Y-axis direction may be the vertical direction.

### <Supplements>

Technical ideas that can be figured out from the embodiment and the change examples will be described below. Note that the reference signs of the constituent elements of the embodiment corresponding to the constituent elements described in the supplements are indicated in parentheses. The reference signs represent examples to aid the understanding, and the constituent elements described in the supplements should not be limited to the constituent elements indicated by the reference signs.

### [Supplement A1]

A semiconductor apparatus including:
a drift region (40);
a body region (42) formed on the drift region (40);
a body contact region (48) formed on the body region (42);
a gate trench (14) formed to penetrate both the body region (42) and the body contact region (48) and reach the drift region (40), the gate trench (14) including a side wall (14A) and a bottom wall (14B);
an insulating layer (16) formed in the gate trench (14);
a gate electrode (50) arranged in the gate trench (14) and separated from the side wall (14A) by the insulating layer (16);
a source region (44) formed along part of the side wall (14A), the source region (44) being in contact with both the body region (42) and the body contact region (48); and
source wiring (28) arranged across both the gate trench (14) and the body region (42) as viewed in a depth direction (Z direction) of the gate trench (14), in which
the source region (44) includes a source contact region (46) that is in contact with the source wiring (28), and
the source wiring (28) is in contact with both a side surface of the source contact region (46) and a front surface of the body contact region (48).

### [Supplement A2]

The semiconductor apparatus according to Supplement A1, in which
the entire front surface of the body contact region (48) is formed as a flat surface without a hole.

### [Supplement A3]

The semiconductor apparatus according to Supplement A1 or A2, in which
the source region (44) is formed to overlap the body contact region (48) as viewed in the depth direction (Z direction).

### [Supplement A4]

The semiconductor apparatus according to Supplement A3, in which
the gate electrode (50) is arranged closer to the bottom wall (14B) of the gate trench (14) in the depth direction (Z direction) than the body contact region (48) is, and
the source region (44) is formed between the body contact region (48) and the gate electrode (50) in the depth direction (Z direction).

### [Supplement A5]

The semiconductor apparatus according to Supplement A4, in which
one of two edges of the source region (44) closer to the bottom wall (14B) of the gate trench (14) is positioned at a same position as a front surface (50B) of the gate electrode (50) in the depth direction (Z direction) or positioned closer to the bottom wall (14B) than the front surface (50B) of the gate electrode (50) is in the depth direction (Z direction).

### [Supplement A6]

The semiconductor apparatus according to Supplement A4 or A5, in which
the source contact region (46) is formed at a position of the source region (44) adjacent to the body contact region (48) in the depth direction (Z direction).

### [Supplement A7]

The semiconductor apparatus according to any one of Supplements A1 to A6, in which
an impurity concentration of the source region (44) is higher than an impurity concentration of the body region (42).

### [Supplement A8]

The semiconductor apparatus according to any one of Supplements A1 to A7, in which
a width dimension (W1) of the source region (44) in a width direction (X direction) of the gate trench (14) is smaller than a depth dimension (W1) of the source region (44) in the depth direction (Z direction).

### [Supplement A9]

The semiconductor apparatus according to Supplement A8, in which
the width dimension (W1) of the source region (44) in the width direction (X direction) is smaller than a width dimension (W2) of the body contact region (48) in the width direction (X direction).

### [Supplement A10]

The semiconductor apparatus according to any one of Supplements A4 to A6, in which
the insulating layer (16) includes
   a first insulating layer (56) that covers a side surface (50C) of the gate electrode (50) and a region between the gate electrode (50) and the bottom wall (14B), and
   a second insulating layer (58) formed on the gate electrode (50),
a front surface (58A) of the second insulating layer (58) is arranged closer to the gate electrode (50) than the front surface of the body contact region (48) is, and
the source wiring (28) is fitted between the front surface of the body contact region (48) and the front surface (58A) of the second insulating layer (58) in the gate trench (14), and the source wiring (28) includes a contact plug (28B) that is in contact with the source contact region (46).

### [Supplement A11]

The semiconductor apparatus according to Supplement A10, in which
a thickness dimension (TC) of the contact plug (28B) in the depth direction (Z direction) is larger than a depth dimension (H2) of the body contact region (48) in the depth direction (Z direction).

### [Supplement A12]

The semiconductor apparatus according to Supplements A10 or A11, in which
a thickness dimension (TC) of the contact plug (28B) in the depth direction (Z direction) is smaller than the depth dimension (H3) of the source region (44) in the depth direction (Z direction).

### [Supplement A13]

The semiconductor apparatus according to any one of Supplements A10 to A2, in which
a thickness dimension (TC) of the contact plug (28B) in the depth direction (Z direction) is equal to or smaller than 1/2 of a distance (DA) between the front surface of the body contact region (48) and the gate electrode (50) in the depth direction (Z direction).

### [Supplement A14]

The semiconductor apparatus according to any one of Supplements A1 to A6, in which
the gate electrode (50) is arranged closer to the body region (42) than the drift region (40).

### [Supplement A15]

The semiconductor apparatus according to any one of Supplements A1 to A14, further including:
an implanted electrode (52) arranged closer to the bottom wall (14B) in the gate trench (14) than the gate electrode (50) is, the implanted electrode (52) being separated from the gate electrode (50), the side wall (14A), and the bottom wall (14B) by the insulating layer (16).

### [Supplement B1]

A manufacturing method of a semiconductor apparatus (10), the manufacturing method including:
forming a semiconductor layer (12) including a first surface (12A) and a second surface (12B) facing an opposite side of the first surface (12A);
forming a gate trench (14) including a side wall (14A) and a bottom wall (14B) in the semiconductor layer (12);
forming a first insulating layer (56) in the gate trench (14);
forming a gate electrode (50) in the gate trench (14);
forming, in the gate trench (14), a second insulating layer (58) that covers a front surface (50B) of the gate electrode (50);
using ion implantation to form a source region (44) at a part of the side wall (14A) of the gate trench (14) closer to the second surface (12B) than the second insulating layer (58);
using ion implantation to form a body region (42) in the semiconductor layer (12);
using ion implantation to form a body contact region (48) in the body region (42); and
forming source wiring (28) in contact with both the source region (44) and the body contact region (48).

### [Supplement B2]

The manufacturing method of the semiconductor apparatus according to supplement B1, in which
the forming the source region (44) includes
   using ion implantation to form a source formation region (108) in the semiconductor layer (12), and
   polishing the second surface (12B) of the semiconductor layer (12) to remove the source formation region (108) formed on the second surface (12B).

### [Supplement B3]

The manufacturing method of the semiconductor apparatus according to supplement B2, in which
the forming the body contact region (48) in the body region (42) is carried out after the source formation region (108) formed on the second surface (12B) is removed.

The description is merely an example. Those skilled in the art can recognize that many more conceivable combinations and replacements can be made in addition to the constituent elements and the methods (manufacturing processes) listed for the purpose of describing the technique of the present disclosure. The present disclosure is intended to include all the substitutions, modifications, and changes included in the scope of the present disclosure including the claims.

What is claimed is:

1. A semiconductor apparatus comprising:
a drift region;
a body region formed on the drift region;
a body contact region formed on the body region;
a gate trench formed to penetrate both the body region and the body contact region and reach the drift region, the gate trench including a side wall and a bottom wall;
an insulating layer formed in the gate trench;
a gate electrode arranged in the gate trench and separated from the side wall by the insulating layer;
a source region formed along part of the side wall, the source region being in contact with both the body region and the body contact region; and
source wiring arranged across both the gate trench and the body region as viewed in a depth direction of the gate trench, wherein
the source region includes a source contact region that is in contact with the source wiring, and
the source wiring is in contact with both a side surface of the source contact region and a front surface of the body contact region.

2. The semiconductor apparatus according to claim 1, wherein
the entire front surface of the body contact region is formed as a flat surface without a hole.

3. The semiconductor apparatus according to claim 1, wherein
the source region is formed to overlap the body contact region as viewed in the depth direction.

4. The semiconductor apparatus according to claim 3, wherein
the gate electrode is arranged closer to the bottom wall of the gate trench in the depth direction than the body contact region is, and
the source region is formed between the body contact region and the gate electrode in the depth direction.

5. The semiconductor apparatus according to claim 4, wherein
one of two edges of the source region closer to the bottom wall of the gate trench is positioned at a same position as a front surface of the gate electrode in the depth direction or positioned closer to the bottom wall than the front surface of the gate electrode is in the depth direction.

6. The semiconductor apparatus according to claim 4, wherein
the source contact region is formed at a position of the source region adjacent to the body contact region in the depth direction.

7. The semiconductor apparatus according to claim 1, wherein
an impurity concentration of the source region is higher than an impurity concentration of the body region.

8. The semiconductor apparatus according to claim 1, wherein
a width dimension of the source region in a width direction of the gate trench is smaller than a depth dimension of the source region in the depth direction.

9. The semiconductor apparatus according to claim 8, wherein
the width dimension of the source region in the width direction is smaller than a width dimension of the body contact region in the width direction.

10. The semiconductor apparatus according to claim 4, wherein
the insulating layer includes
a first insulating layer that covers a side surface of the gate electrode and a region between the gate electrode and the bottom wall, and
a second insulating layer formed on the gate electrode,
a front surface of the second insulating layer is arranged closer to the gate electrode than the front surface of the body contact region is, and
the source wiring is fitted between the front surface of the body contact region and the front surface of the second insulating layer in the gate trench, and the source wiring includes a contact plug that is in contact with the source contact region.

11. The semiconductor apparatus according to claim 10, wherein
a thickness dimension of the contact plug in the depth direction is larger than a depth dimension of the body contact region in the depth direction.

12. The semiconductor apparatus according to claim 10, wherein
a thickness dimension of the contact plug in the depth direction is smaller than the depth dimension of the source region in the depth direction.

13. The semiconductor apparatus according to claim 10, wherein
a thickness dimension of the contact plug in the depth direction is equal to or smaller than ½ of a distance between the front surface of the body contact region and the gate electrode in the depth direction.

14. The semiconductor apparatus according to claim 4, wherein
the gate electrode is arranged closer to the body region than the drift region.

15. The semiconductor apparatus according to claim 1, further comprising:
an implanted electrode arranged closer to the bottom wall in the gate trench than the gate electrode is, the implanted electrode being separated from the gate electrode, the side wall, and the bottom wall by the insulating layer.
